(19) United States
(12) Patent Application Publication
(10) Pub. No.: US 2011/0241808 A1
(43) Pub. Date: Oct. 6, 2011

(54) Tuner Module

(76) Inventors: Haiyan Zhao, Fukaya-shi (JP); Masahiro Kobayashi, Kasu-shi (JP); Noriaki Sakamoto, Honjo-shi (JP)

(21) Appl. No.: 12/987,731

(22) Filed: Jan. 10, 2011

(30) Foreign Application Priority Data
Mar. 31, 2010 (JP) 2010-084355

(51) Int. Cl. H03J 3/02

(52) U.S. Cl. 334/85

(57) ABSTRACT

According to one embodiment, a tuner module, including: a substantially box-shaped casing; an input terminal attached to one side plate of the casing; a distributor disposed in the casing around the input terminal; a first tuner disposed adjoining the distributor so as to sandwich the distributor with the input terminal; a second tuner disposed adjoining the first tuner so as to sandwich the first tuner with the distributor; and a circuit board on which the distributor, the first tuner and the second tuner are mounted.

### CROSS-REFERENCE TO RELATED APPLICATION(S)

This application is based upon and claims the benefit of priority from Japanese Patent Application No. 2010-084355, filed on Mar. 31, 2010, the entire contents of which are incorporated herein by reference.

### FIELD

Embodiments described herein relate generally to a tuner module for receiving broadcast waves.

### BACKGROUND

In order to receive plural broadcast signals, such as a terrestrial analog broadcast signal, a terrestrial digital broadcast signal and a satellite digital broadcast signal, it is required to provide a receiving apparatus with plural tuners. In the digital broadcast, due to increase in the number of channels, not only the number of programs attractive to the viewer but also the broadcast time thereof increase. Thus, overlapping of the broadcast times of programs occurs. Thus, a viewer's chance of recording a program and viewing, when convenient for the viewer, the recorded program has been increased. Accordingly, the receiving apparatus needs to have plural digital broadcast tuners.

Hitherto, to provide the tuner module capable of simultaneously receiving a digital broadcast and analog broadcast, or two digital broadcasts, two tuner modules housed in respective casings are connected to each other with a cable, or the casings of the two tuners have simply been united with each other.

In this case, the area occupied by the tuner module provided on the circuit board increases. In view of above, two tuners may be mounted in one conventional casing.

However, when two tuners are arranged close to each other, the interference between the local oscillators in the respective tuners may occur. A method of dealing with such interference has been proposed (see JP-2005-318053-A).

In order to reduce the size and the thickness of the receiving apparatus, the tuner module having a built-in tuner adapted to receive a digital broadcast and an analog broadcast or to simultaneously receive plural digital broadcasts is also demanded to reduce the size thereof. In order to reduce the size of the tuner module, circuit components of the tuner module are highly densely packed therein, so that the distance between the tuners is decreased. However, in this case, the mutual interference between the tuners may occur.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 is a perspective view illustrating a horizontal-type tuner module according to Embodiment 1.

FIG. 2 illustrates the structure of the tuner module according to Embodiment 1.

FIG. 3 illustrates a block diagram of the tuner module according to Embodiment 1.

FIG. 4 is a perspective view illustrating the structure of the tuner module according to Embodiment 1.

FIG. 5 illustrates the structure of a tuner module according to Embodiment 2.

FIG. 6 illustrates the structure of a tuner module according to Embodiment 3.

FIG. 7 illustrates the structure of a tuner module according to Embodiment 4.

FIG. 8 is a perspective view illustrating the structure of the tuner module according to Embodiment 4.

### DETAILED DESCRIPTION

In general, according to one embodiment, there is provided a tuner module, including: a substantially box-shaped casing; an input terminal attached to one side plate of the casing; a distributor disposed in the casing around the input terminal; a first tuner disposed adjoining the distributor so as to sandwich the distributor with the input terminal; a second tuner disposed adjoining the first tuner so as to sandwich the first tuner with the distributor; and a circuit board on which the distributor, the first tuner and the second tuner are mounted.

Hereinafter, embodiments are described with reference to the drawings.

### Embodiment 1

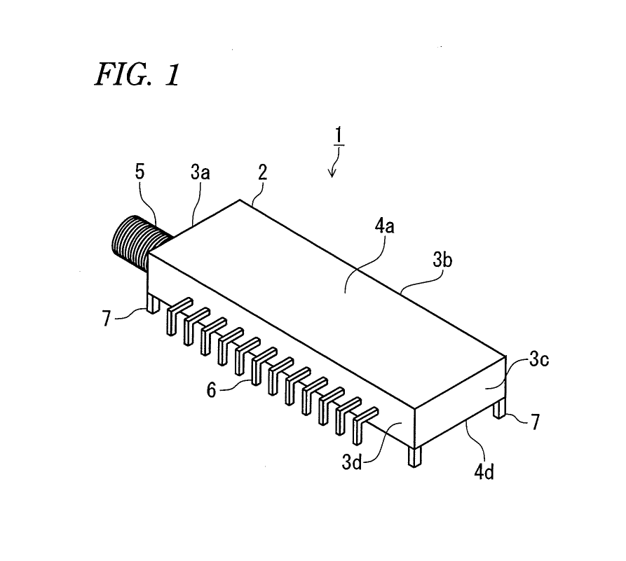

FIG. 1 is a perspective view illustrating a horizontal-type tuner module according to Embodiment 1. The tuner module 1 is covered with a substantially rectangular-parallelepiped-shaped metal casing 2. The casing 2 includes side plates 3a, 3b, 3c, and 3d and top/bottom plates 4a and 4b adjoining the side plates. An input terminal 5 to receive signals from an antenna is arranged at the side plate 3a.

Plural legs 7 for fixing plural output terminals 6 and the tuner module 1 to a circuit board in the receiving apparatus (not shown) are attached to the side plate 3d. The output terminals 6 and the legs 7 can be attached to either the side plate 3b or the top/bottom plate 4a or 4b.

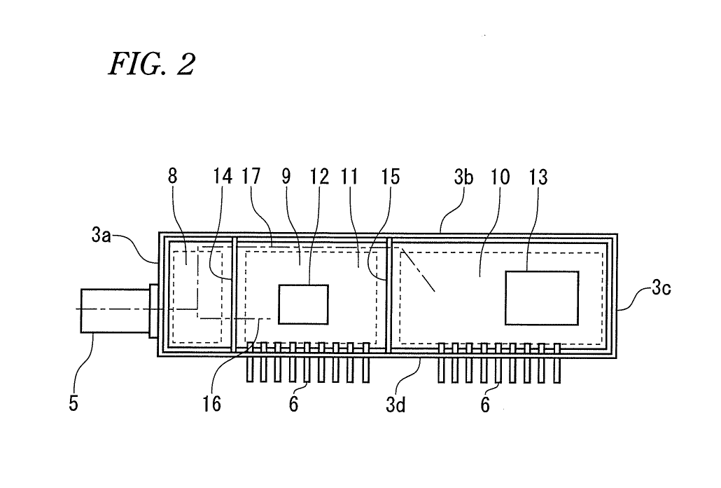

FIG. 2 illustrates the structure of the tuner module 1 according to Embodiment 1. In FIG. 2, the tuner module 1 is viewed from the side of the bottom plate 4b in a state where the bottom plate 4b is removed therefrom. A distributor built-in input block 8 indicated with dashed lines, which includes a distributor, is placed around the input terminal 5 in the casing 2. A silicon tuner block 9 serving as a first tuner, which is indicated with dashed lines, is placed next to the distributor built-in input block 8 at the side opposite to the input terminal 5 and placed at the rear side in the longitudinal direction of a substantially rectangular-parallelepiped-shaped casing 2. A discrete tuner block 10 serving as a second tuner, which is indicated with dashed lines, is placed next to the silicon tuner block 9 on the opposite side of the distributor built-in input block 8 and placed at the further rear side in the longitudinal direction of the substantially rectangular-parallelepiped-shaped casing 2. Accordingly, the input terminal 5, the distributor built-in input block 8, the silicon tuner block 9, and the discrete tuner block 10 are provided in a linear arrangement in this order.

The distributor built-in input block 8, the silicon tuner block 9, and the discrete tuner block 10 are mounted on a circuit board 11. The circuit board 11 is an integrated component. The outer shape of the circuit board 11 is formed substantially along the inner shape of the casing 2.

A first barrier plate 14 is disposed between the distributor built-in input block 8 and the silicon tuner block 9. A second barrier plate 15 is disposed between the silicon tuner block 9 and the discrete tuner block 10.

A wire 16 (indicated with alternate long and short dash lines) for inputting signals to the silicon tuner block 9 from the distributor built-in input block 8 is arranged on the circuit board 11. A wire 17 (indicated with alternate long and short dash lines) for inputting signals to the discrete tuner block 10 from the distributor built-in input block 8 is also arranged thereon. The wire 17 is placed around the casing of the silicon tuner block 9 (i.e., around the side plate 3b) on the circuit board 11.

The “silicon tuner” of the silicon tuner block 9 is a tuner using a silicon tuner integrated circuit (IC) 12. The silicon tuner IC 12 is a tuner circuit component obtained by configuring, with semiconductor chips, functional components, e.g., an IC containing a mixer, a phase locked loop (PLL), and the like hitherto used in a discrete tuner, and an air-cored coil having a diameter of about several millimeters (mm), and a varactor diode, which configure an analog portion of a filter or the like. Almost all of circuits necessary for receiving signals, except a part of such circuits, are contained in a semiconductor. Thus, the silicon tuner IC 12 can be miniaturized.

The “discrete tuner” of the discrete tuner block 10 is a tuner obtained by configuring, with discrete components, functional components, e.g., a frequency conversion IC 13 containing a mixer, a PLL, and the like, and an air-cored coil having a diameter of about several mm, and a varactor diode, which configure an analog portion of a filter or the like. Although the packaging area of the discrete tuner is large, generally, the discrete tuner is more desirable in the high-frequency properties than the silicon tuner. Thus, the discrete tuner is frequently used as a tuner for both analog broadcasting and digital broadcasting.

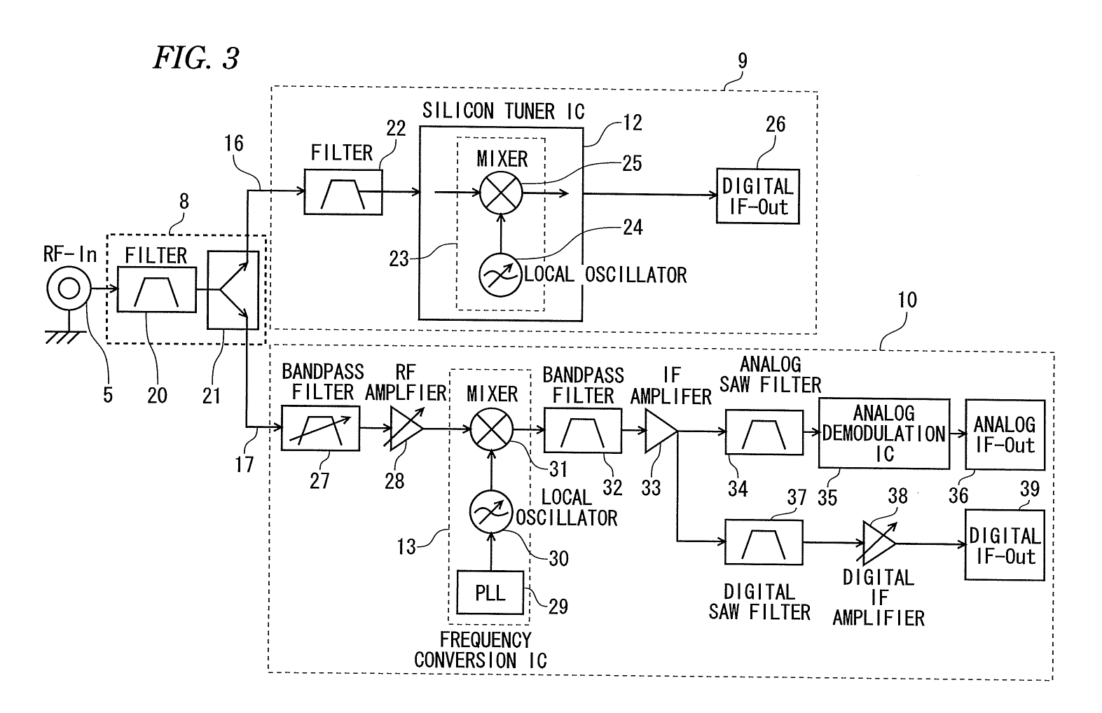

FIG. 3 illustrates a block diagram of the tuner module according to Embodiment 1. High frequency signals obtained from broadcast waves are input to the distributor built-in input block 8 from the input terminal 5. In the distributor built-in input block 8, the high-frequency signals pass through a filter 20 and are input to a distributor 21. One of the high-frequency signals output from the distributor 21 is input to the silicon tuner block 9 via a wire 16. The other signal is input to the discrete tuner block 10 via a wire 17.

In the silicon tuner block 9, the high-frequency signal is input to the silicon tuner IC 12 after passing through the filter 22. Although the detailed description of operations in the silicon tuner IC 12 is omitted, a local oscillator 24 and a mixer 25 are provided in a frequency conversion portion 23. The high-frequency signal is converted into an intermediate frequency (IF) signal to be demodulated. Then, the IF signal is output to a digital IF-Out portion 26.

On the other hand, in the discrete tuner block 10, a desired channel frequency signal is extracted by a bandpass filter 27. Next, the extracted signal is amplified by a radio frequency (RF) amplifier 28. The amplified signal is input to the frequency conversion IC 13. In the frequency conversion IC 13, a local oscillator 30 generates a signal having a frequency based on an output of the PLL. Then, a mixer 31 converts, into an IF signal to be demodulated, the input signal, using the generated signal. The converted signal output by the mixer 31 passes through a bandpass filter 32. Then, the signal passing through the bandpass filter 32 is amplified by an IF amplification amplifier 33. After that, the amplified signal is input to an analog surface acoustic wave (SAW) filter 34 and a digital SAW filter 37.

A signal output from the analog SAW filter 34 is demodulated by an analog demodulation IC 35. The demodulated signal is output therefrom to an analog IF-Out portion 36. A signal output from the digital SAW filter 37 is amplified by a digital IF amplifier 38. The amplified signal is output therefrom to a digital IF-Out portion 39.

The silicon tuner IC 12 of the silicon tuner block 9, and the frequency conversion IC 13 of the discrete tuner block contains the local oscillators 24 and 30, respectively. Thus, it is necessary to suppress the mutual interference caused by the local oscillators 24 and 30. The input terminal 5, the distributor built-in input block 8, the silicon tuner block 9, and the discrete tuner block 10 are placed in a linear arrangement in this order. The second barrier plate 15 is placed between the silicon tuner block 9 and the discrete tuner block 10. The distance between the silicon tuner IC 12 and the frequency conversion IC 13 is set at a large value. Thus, the influence of the interference between the local oscillators can be suppressed.

The radiation of the local oscillator 24 of the silicon tuner IC 12 is weaker than the radiation of the local oscillator 30 of the frequency conversion IC 13 of the discrete tuner block 10. Accordingly, the silicon tuner block 9 is disposed between the distributor built-in input block 8 and the discrete tuner block 10. Thus, influence of the jumping of a local oscillation signal from the local oscillator 24 to the wire 17 extending from the distributor built-in block 8 to the discrete tuner block 10 is low. In addition, because the silicon tuner IC 12 doesn't include an air-cored coil as the discrete tuner block 10 includes, there is no coupling between the coil and the signal line.

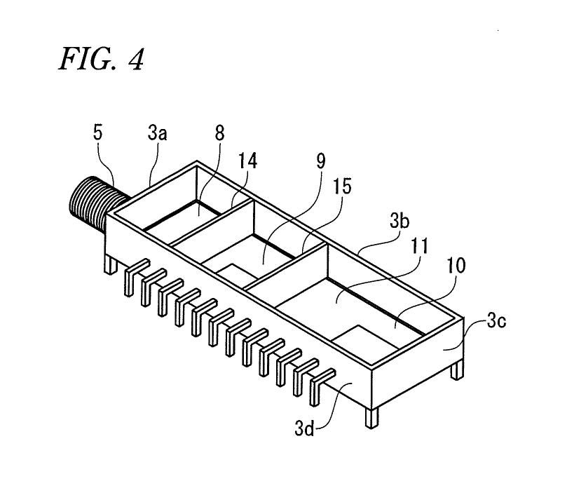

FIG. 4 is a perspective view illustrating the structure of the tuner module according to Embodiment 1. As illustrated in FIG. 4, the first barrier plate 14 is arranged to extend from the side plate 3b to the side plate 3d to partition between the distributor built-in input block 8 and the silicon tuner block 9. The second barrier plate 15 is arranged to extend from the side plate 3b to the side plate 3d to partition between the silicon tuner block 9 and the discrete tuner block 10. The first barrier plate 14 and the second barrier plate 15 are made of metal. Preferably, the materials of the first barrier plate 14 and the second barrier plate 15 are the same as that of the casing 2. The first barrier plate 14 and the second barrier plate 15 are electrically connected to the side plate 3b and the side plate 3d, respectively. Thus, the influence of the mutual interference between the local oscillators can be suppressed. The tuner module having plural built-in tuners provided in the single casing can stably receive signals with low interference between the tuners.

### Embodiment 2

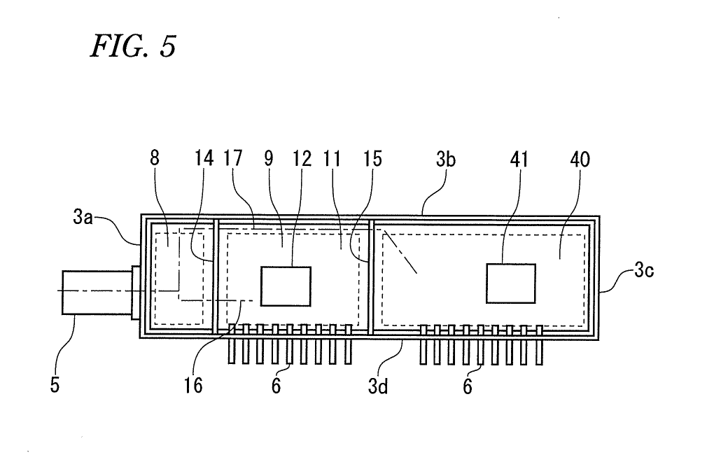

FIG. 5 illustrates the structure of a tuner module according to Embodiment 2. Each portion of Embodiment 2, which is the same as an associated portion of the tuner module of Embodiment 1 illustrated in FIG. 2, is designated with the same reference numeral. Embodiment 2 differs from Embodiment 1 in that the discrete tuner block 10 serving as the second tuner in Embodiment 1 is replaced with a silicon tuner block 40 in Embodiment 2.

The radiation of each of the silicon tuners IC 12 and IC 14 is weak. Influence of the jumping of a local oscillation signal to the wire 17 is small. In addition, the silicon tuners IC 12 and IC 14 don't contain an air-cored coil as the discrete tuner block has. Accordingly, there is no coupling between the coil and the signal line. The input terminal 5, the distributor built-in input block 8, the silicon tuner block 9 and the silicon tuner block 40 are placed in a linear arrangement. The second barrier plate 15 is placed between the silicon tuner block 9 and the silicon tuner block 40. The distance between the silicon tuners IC 12 and IC 14 is set at a large value. Thus, the influence of the interference between the local oscillators can be suppressed.

### Embodiment 3

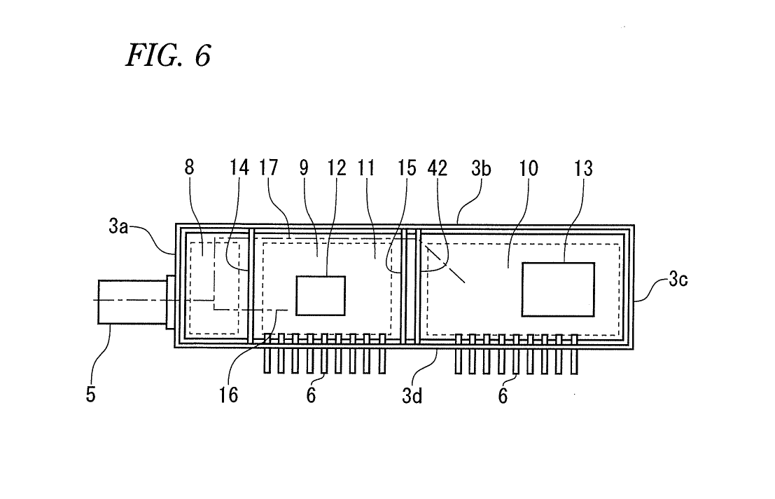

FIG. 6 illustrates the structure of a tuner module according to Embodiment 3. Each portion of Embodiment 3, which is the same as an associated portion of the tuner module of Embodiment 1 illustrated in FIG. 2, is designated with the same reference numeral. Embodiment 3 differs from Embodiment in that a third barrier plate 42 is additionally provided between the silicon tuner block 9 serving as the first tuner and the discrete tuner block 10 serving as the second tuner.

The third barrier plate 42 is disposed around the second barrier plate 15 substantially in parallel to the second barrier plate 15. The material of the third barrier plate 42 is the same as that of the second barrier plate 15. The third barrier plate 42 is electrically connected to the side plates 3b and 3d. The interference between the local oscillators of the first tuner and the second tuner can be reduced by setting a structure in which the barrier plates 15 and 42 are doubly provided between the first tuner and the second tuner. In addition, additional interference between the tuner circuits can also be suppressed.

### Embodiment 4

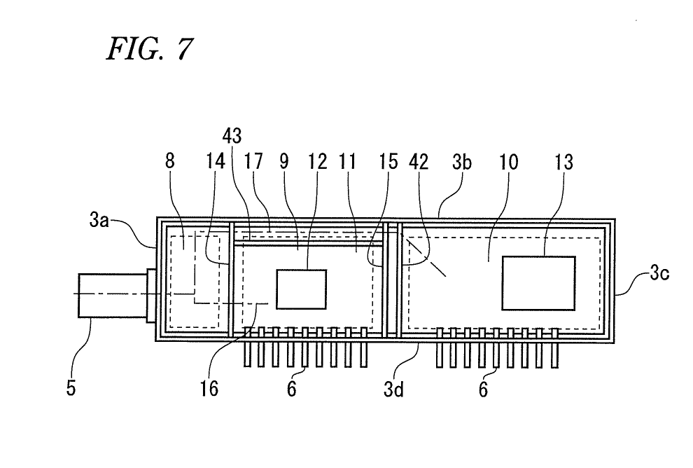

FIG. 7 illustrates the structure of a tuner module according to Embodiment 4. Each portion of Embodiment 4, which is the same as an associated portion of the tuner module of Embodiment 3 illustrated in FIG. 6, is designated with the same reference numeral. Embodiment 4 differs from Embodiment 3 in that a fourth barrier plate 43 is provided between the first tuner and the wire 17.

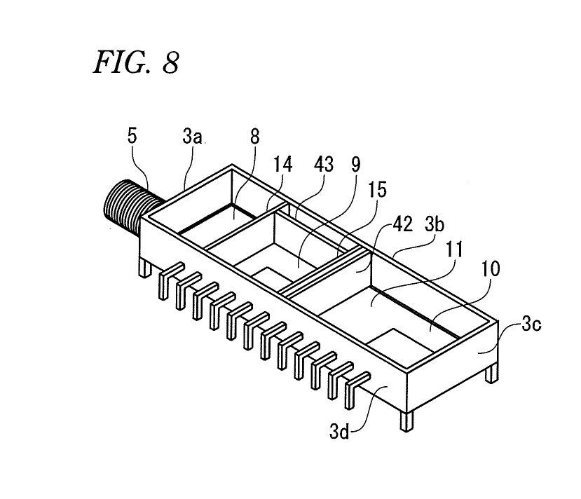

FIG. 8 is a perspective view illustrating the structure of the tuner module according to Embodiment 4. The fourth barrier plate 43 is disposed to extend from the first barrier plate 14 to the second barrier plate 15 substantially in parallel to the side plate 3b. The fourth barrier plate 43 is made of metal. Preferably, the material of the fourth barrier plate 43 is the same as that of each of the first barrier plate 14 and the second barrier plate 15. The fourth barrier plate 43 is electrically connected to each of the first barrier plate 14 and the second barrier plate 15. The influence of the radiation to the wire 17 from the local oscillator 24 of the silicon tuner block 9 serving as the first tuner is reduced. The coupling between the air-cored coil of the discrete tuner block 10 and the signal line can be avoided. In addition, other noises can be prevented from being mixed into the wire 17. Unnecessary radiation can be prevented from affecting the wire 17. Accordingly, the tuner module according to Embodiment 4 can stably receive signals with low interference between the tuners.

The invention is not limited to the above embodiment, and can be embodied by changing the components thereof without departing from the scope of the invention. Various inventions can be accomplished by appropriately combining plural components disclosed in the above embodiment. For example, several components may be deleted from all the components described in the embodiment, and components of different embodiments can appropriately be combined.

What is claimed is:

1. A tuner module, comprising:
a substantially box-shaped casing;
an input terminal attached to one side plate of the casing;
a distributor disposed in the casing around the input terminal;
a first tuner disposed adjoining the distributor so as to sandwich the distributor with the input terminal;
a second tuner disposed adjoining the first tuner so as to sandwich the first tuner with the distributor; and
a circuit board on which the distributor, the first tuner and the second tuner are mounted.

2. The tuner module of claim 1, further comprising:
a first barrier plate provided between the distributor and the first tuner.

3. The tuner module of claim 2, further comprising:
a second barrier plate provided between the first tuner and the second tuner.

4. The tuner module of claim 3, further comprising:
a third barrier plate provided between the first tuner and the second tuner.

5. The tuner module of claim 3, further comprising:
a wire disposed on the circuit board around a casing of the first tuner, while extending from the distributor to the second tuner; and
a fourth barrier plate provided between the first tuner and the wire.

6. The tuner module of claim 1,
wherein the first tuner is a silicon tuner; and
wherein the second tuner is a discrete tuner.

7. The tuner module of claim 1,
wherein the first tuner and the second tuner are silicon tuners.
